(19) United States
(12) Patent Application Publication
(10) Pub. No.: US 2011/0317731 A1
(43) Pub. Date: Dec. 29, 2011

(54) SEMICONDUCTOR DEVICE

(75) Inventor: Tohru Takiguchi, Tokyo (JP)

(73) Assignee: MITSUBISHI ELECTRIC CORPORATION, Tokyo (JP)

(21) Appl. No.: 13/015,797

(22) Filed: Jan. 28, 2011

(30) Foreign Application Priority Data
Jun. 25, 2010 (JP) 2010-145076

(51) Int. Cl. H01S 5/323; H01S 5/343

(52) U.S. Cl. 372/45.011

(57) ABSTRACT

A semiconductor laser includes a P-type InP substrate and a P-type InP cladding layer, an AlGaInAs strained quantum well active layer, an N-type InP cladding layer, a P-type InP buried layer, an N-type InP buried layer, a P-type InP buried layer, an N-type InP layer, an N-type InP contact layer, an SiO₂ insulating film, an N-type electrode, and an electrode, all disposed on the P-type InP substrate. Further, the semiconductor laser includes an N-type InGaAsP layer.

### FIELD OF THE INVENTION

The present invention relates to a semiconductor device.

### BACKGROUND ART

Semiconductor devices including N-type and P-type semiconductor layers stacked in an interleaved fashion have been known as well as semiconductor lasers including a current blocking layer having such a device structure, as disclosed in, e.g., Japanese Laid-Open Patent Publication No. H06-21566.

Japanese Laid-Open Patent Publication No. 2001-111170 and Japanese Laid-Open Patent Publication No. 2001-111170 are also disclosing conventional semiconductor devices.

FIG. 19 is across-sectional view of a conventional semiconductor device (namely, a semiconductor laser), and will be used to describe the problems sought to be overcome by the present invention.

The semiconductor laser shown in FIG. 19 includes a P-type InP substrate 1, a P-type InP cladding layer 2 (having a P-type carrier concentration of 1×10¹⁸ cm⁻³), an AlGaInAs strained quantum well active layer 3, an N-type InP cladding layer 4 (having an N-type carrier concentration of 1×10¹⁸ cm⁻³), a P-type InP buried layer 5 (having a P-type carrier concentration of 1×10¹⁸ cm⁻³), an N-type InP buried layer 6 (having an N-type carrier concentration of 1×10¹⁹ cm⁻³), a P-type InP buried layer 7 (having a P-type carrier concentration of 1×10¹⁸ cm⁻³), an N-type InP layer 8 (having an N-type carrier concentration of 1×10¹⁸ cm⁻³), an N-type InP contact layer 9 (having an N-type carrier concentration of 1×10¹⁹ cm⁻³), an SiO₂ insulating film 10, an N-type electrode 11 of Ti/Pt/Au, and a P-type electrode 12 of Ti/Pt/Au.

In the structure shown in FIG. 19, the P-type InP buried layer 5, the N-type InP buried layer 6, and the P-type InP buried layer 7 together function as a current blocking layer. In FIG. 20, arrow A schematically illustrates a leakage current flowing vertically through the current blocking layer. The present inventor has intensively studied the phenomenon of a large leakage current flowing vertically through the current blocking layer, as indicated by arrow A in FIG. 20. The reason is that such a large leakage current causes degradation of the semiconductor characteristics, specifically, the current-light output characteristic of the semiconductor laser.

### SUMMARY OF THE INVENTION

The present invention has been made to solve this problem. It is, therefore, an object of the present invention to provide a semiconductor device having a structure which allows for reduction of the leakage current flowing through the current blocking layer.

To achieve the above-mentioned purpose, a first aspect of the present invention is a semiconductor device including a current blocking layer, a first N-type semiconductor layer and a second N-type semiconductor layer. The current blocking layer according to the first aspect has a layer stack structure including a P-type semiconductor layer, an N-type semiconductor layer, and another P-type semiconductor layer stacked on one another in that order. The first N-type semiconductor layer according to the first aspect covers the current blocking layer. The second N-type semiconductor layer according to the first aspect is formed between the first N-type semiconductor layer and the another P-type semiconductor layer of the current blocking layer and in contact with the another P-type semiconductor layer. The second N-type semiconductor layer according to the first aspect has a smaller bandgap than the first N-type semiconductor layer so that the another P-type semiconductor layer has a higher potential barrier than in the absence of the second N-type semiconductor layer.

To achieve the above-mentioned purpose, a second aspect of the present invention is a semiconductor device including a current blocking layer. The current blocking layer according to the second aspect has a layer stack structure including a P-type semiconductor layer, an N-type semiconductor layer, and another P-type semiconductor layer stacked on one another in that order. The N-type semiconductor layer according to the second aspect is an InGaAsP or AlGaInAs layer.

To achieve the above-mentioned purpose, a third aspect of the present invention is a semiconductor device including a current blocking layer. The current blocking layer according to the third aspect has a layer stack structure including a P-type semiconductor layer, an N-type semiconductor layer, and a semi-insulating semiconductor layer stacked on one another in that order. The N-type semiconductor layer according to the third aspect is an InGaAsP or AlGaInAs layer.

In accordance with the present invention, the leakage current flowing through the current blocking layer is reduced by disposing an N-type semiconductor layer having a small bandgap at a specific location and thereby increasing the potential barrier.

### BRIEF DESCRIPTION OF THE DRAWINGS

FIG. 1 is a cross-sectional view of a semiconductor laser which is a semiconductor device according to a first embodiment of the present invention.

FIG. 2 is a diagram showing the current-light output characteristics of the semiconductor laser according to the first embodiment of the present invention.

FIG. 3 is a diagram showing the conduction band profiles of the semiconductor laser according to the first embodiment of the present invention.

FIG. 4 is a diagram showing the current-light output characteristics of the semiconductor laser according to the first embodiment of the present invention.

FIG. 5 is a diagram showing the conduction band profiles of the semiconductor laser according to the first embodiment of the present invention.

FIG. 6 is a cross-sectional view of a semiconductor laser according to a second embodiment of the present invention.

FIG. 7 is a cross-sectional view of a semiconductor laser according to a third embodiment of the present invention.

FIG. 8 is a cross-sectional view of a semiconductor laser according to a fourth embodiment of the present invention.

FIG. 9 is a cross-sectional view of a semiconductor laser according to a fifth embodiment of the present invention.

FIG. 10 is a cross-sectional view of a semiconductor laser according to a sixth embodiment of the present invention.

FIG. 11 is a cross-sectional view of a semiconductor laser according to a seventh embodiment of the present invention.

FIG. 12 is a diagram illustrating a method of manufacturing a semiconductor laser according to the first embodiment.

FIG. 13 is a diagram illustrating a method of manufacturing a semiconductor laser according to the first embodiment.

FIG. 14 is a diagram illustrating a method of manufacturing a semiconductor laser according to the first embodiment.

FIG. 15 is a diagram illustrating a method of manufacturing a semiconductor laser according to the first embodiment.

FIG. 16 is a diagram illustrating a method of manufacturing a semiconductor laser according to the first embodiment.

FIG. 17 is a diagram illustrating a method of manufacturing a semiconductor laser according to the first embodiment.

FIG. 18 is a diagram illustrating a method of manufacturing a semiconductor laser according to the first embodiment.

FIG. 19 is a cross-sectional view of a semiconductor laser, and will be used to describe the problems sought to be overcome by the present invention.

FIG. 20 is a diagram illustrating a leakage current flowing in a semiconductor laser, and will be used to describe the problems sought to be overcome by the present invention.

### DETAILED DESCRIPTION OF THE PREFERRED EMBODIMENTS

### First Embodiment

### Structure of First Embodiment

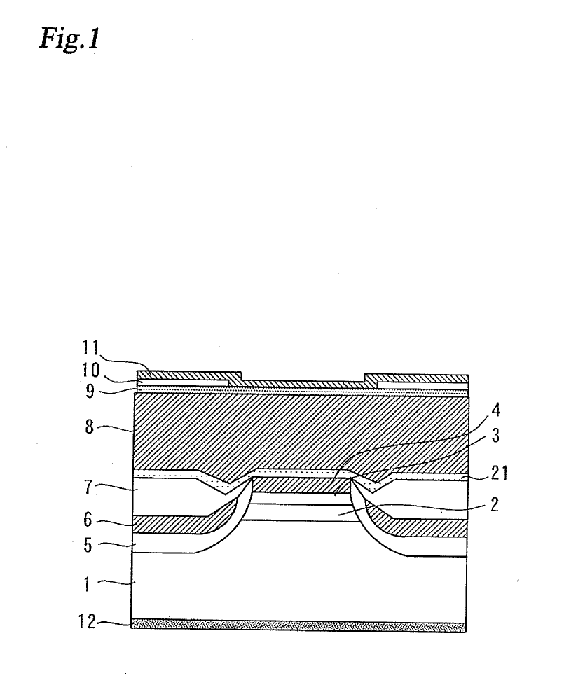

FIG. 1 is a cross-sectional view of a semiconductor laser which is a semiconductor device according to a first embodiment of the present invention. As shown in this figure, the semiconductor laser of the present embodiment includes a P-type InP substrate 1. The semiconductor laser of the present embodiment also includes a P-type InP cladding layer 2 (having a P-type carrier concentration of 1×10¹⁸ cm⁻³), an AlGaInAs strained quantum well active layer 3, and an N-type InP cladding layer 4 (having an N-type carrier concentration of 1×10¹⁸ cm⁻³) disposed in succession on the P-type InP substrate 1, as seen at the center of the cross-sectional view of FIG. 1.

The semiconductor laser of the present embodiment further includes a P-type InP buried layer 5 (having a P-type carrier concentration of 1×10¹⁸ cm⁻³), an N-type InP buried layer 6 (having an N-type carrier concentration of 1×10¹⁹ cm⁻³), and a P-type InP buried layer 7 (having a P-type carrier concentration of 1×10¹⁸ cm⁻³), as seen at the right and left sides of the cross-sectional view of FIG. 1.

As shown, the semiconductor laser of the present embodiment further includes an N-type InP layer 8 (having an N-type carrier concentration of 1×10¹⁸ cm⁻³), an N-type InP contact layer 9 (having an N-type carrier concentration of 1×10¹⁹ cm⁻³), an SiO² insulating film 10, an N-type electrode 11 of Ti/Pt/Au, and a P-type electrode 12 of Ti/Pt/Au.

As shown, the semiconductor laser of the present embodiment still further includes an N-type InGaAsP layer 21 (having an N-type carrier concentration of 1×10¹⁸ cm⁻³). The N-type InGaAsP layer 21 is located between the P-type InP buried layer 7 and the N-type InP layer 8.

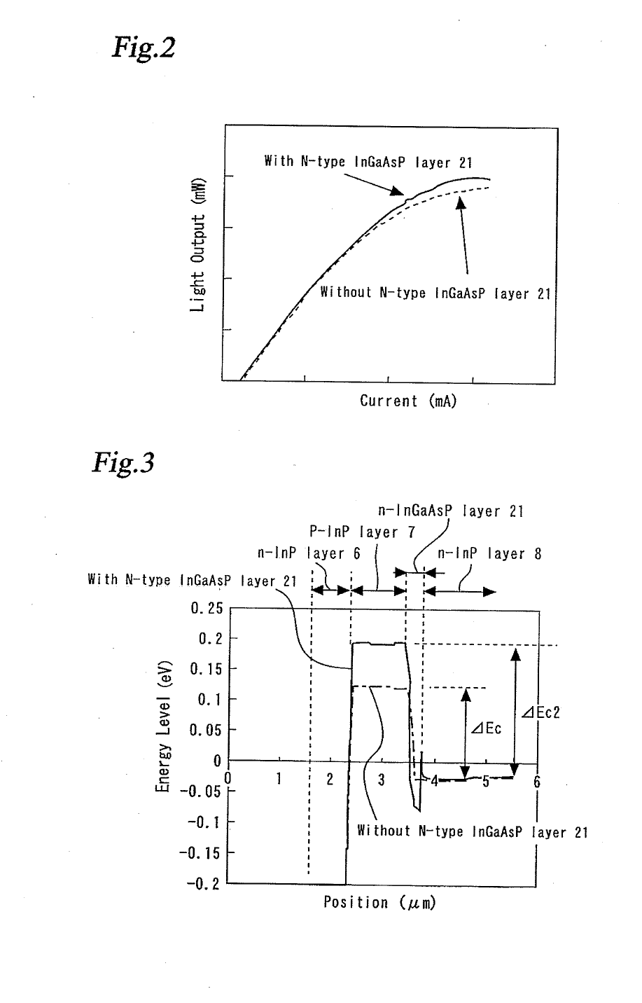

FIG. 2 is a diagram showing the current-light output characteristics at 75° C. of the semiconductor laser with the N-type InGaAsP layer 21 (having a bandgap wavelength of 1.10 μm) and a comparative semiconductor laser having a similar structure but without the N-type InGaAsP layer 21. As can be seen, the presence of the N-type InGaAsP layer 21 reduces the leakage current and thereby increases the light output.

This function of the N-type InGaAsP layer 21 will now be described. FIG. 3 shows the conduction band profiles of the semiconductor laser with the N-type InGaAsP layer 21 (having a bandgap wavelength of 1.10 μm) and the comparative semiconductor laser having a similar structure but without the N-type InGaAsP layer 21. Referring to FIG. 3, electrons injected into the N-type InP layer 8 (shown at the right side of FIG. 3) pass over the potential barrier of the P-type InP buried layer 7 into the N-type InP buried layer 6, forming a current. This current is referred to as a “leakage current.”

The higher the potential barrier, the fewer electrons pass over the barrier, and hence the lower the leakage current. As shown in FIG. 3, the P-type InP buried layer 7 of the semiconductor laser of the present embodiment having the N-type InGaAsP layer 21 has a potential barrier ΔEc2 which is higher than the potential barrier ΔEc of the P-type InP buried layer 7 of the comparative semiconductor laser. Thus the present embodiment increases the potential barrier and reduces the leakage current in the semiconductor laser.

Thus, in the semiconductor laser of the first embodiment, the N-type InGaAsP layer 21 is interposed in the manner described above to reduce the leakage current and increase the light output, as shown in FIG. 2.

It should be noted that the N-type InGaAsP layer 21 of the first embodiment corresponds to the second N-type semiconductor layer of the first aspect of the present invention described in the Summary of the Invention section.

Although in the first embodiment an InGaAsP layer (namely, the N-type InGaAsP layer 21) is interposed in the manner described above, it is to be understood that the present invention is not limited to this particular structure. For example, the N-type InGaAsP layer 21 may be replaced by a layer of material other than InGaAsP and having a smaller bandgap than InP. Such structures still have a leakage current reducing effect similar to that described in connection with the first embodiment. For example, the layer material may be AlGaInAs, instead of InGaAsP, with the same leakage current reducing effect.

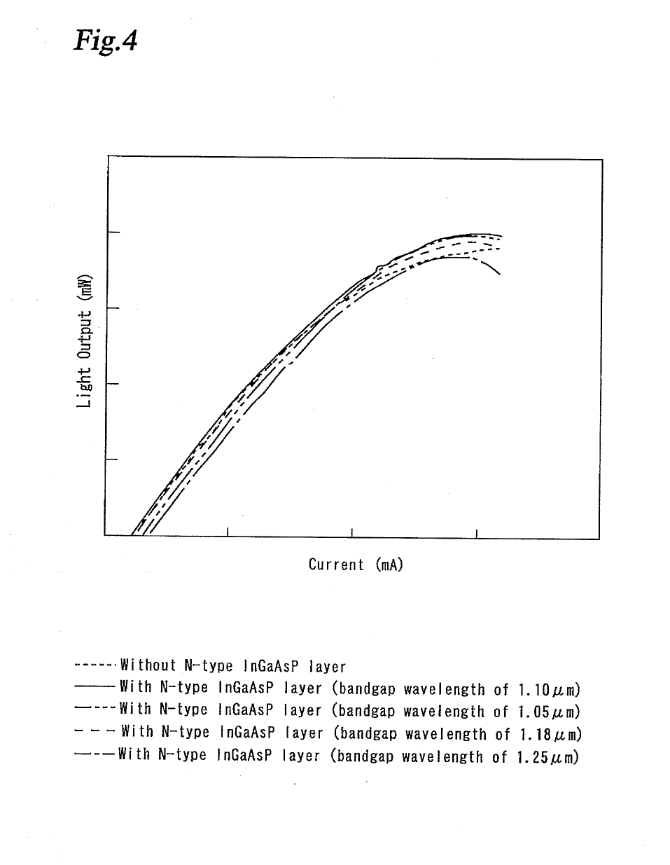

FIG. 4 is a diagram showing the current-light output characteristics at 75° C. of the semiconductor laser for different bandgap wavelengths of the N-type InGaAsP layer 21. FIG. 4 also shows the current-light output characteristic at 75° C. of the semiconductor laser in the absence of the N-type InGaAsP layer 21. This characteristic is indicated by dashed line in FIG. 4. Further, in FIG. 4, the current-light output characteristics of the semiconductor laser for different bandgap wavelengths of the N-type InGaAsP layer 21 are indicated by solid line for a bandgap wavelength of 1.10 μm, chain double-dashed line for a bandgap wavelength of 1.05 μm, coarse dashed line for a bandgap wavelength of 1.18 μm, and chain line for a bandgap wavelength of 1.25 μm. Comparison of these current-light output characteristics with that of the semiconductor laser without the N-type InGaAsP layer 21 reveals that the semiconductor laser with the N-type InGaAsP layer 21 has a better current-light output characteristic than the semiconductor laser without the N-type InGaAsP layer 21 when the bandgap wavelength of the N-type InGaAsP layer 21 is 1.10 μm, 1.05 μm, and 1.18 μm. Thus, as compared to the semiconductor laser without the N-type InGaAsP layer 21, the semiconductor laser with the N-type InGaAsP layer 21 has a significantly better current-light output characteristic when the layer 21 has a bandgap wavelength of 1.05-1.2 μm.

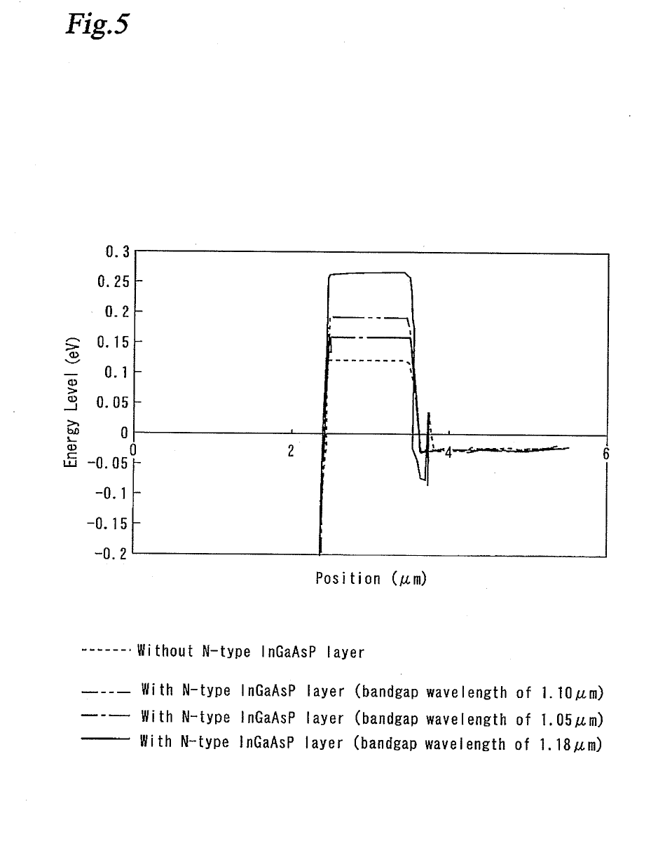

FIG. 5 is a diagram showing the conduction band profiles of the semiconductor laser for different bandgap wavelengths of the N-type InGaAsP layer 21. The longer the bandgap wavelength of the N-type InGaAsP layer 21, the higher the potential barrier ΔEc of the P-type InP buried layer 7, and hence the greater the leakage current reducing effect of the P-type InP buried layer 7. However, the longer the bandgap wavelength of the N-type InGaAsP layer 21, the higher the Auger recombination current, and hence the higher the threshold current. An increase in the threshold current degrades the current-light output characteristic of the semiconductor laser. For these reasons, the semiconductor laser with the N-type InGaAsP layer 21 has a significantly better current-light output characteristic than the semiconductor laser without the N-type InGaAsP layer 21 when the layer 21 has a bandgap wavelength of 1.05-1.2 μm.

The following should be noted: the combination of the P-type InP buried layer 5, the N-type InP buried layer 6, and the P-type InP buried layer 7 of the first embodiment described above corresponds to the current blocking layer of the first aspect of the present invention described in the Summary of the Invention section; the N-type InP layer 8 corresponds to the first N-type semiconductor layer of the first aspect; and the N-type InGaAsP layer 21 corresponds to the second N-type semiconductor layer of the first aspect.

### Manufacturing Method of First Embodiment

FIGS. 12 to 18 are diagrams illustrating a method of manufacturing a semiconductor laser according to the first embodiment.

As shown in FIG. 12, a P-type InP cladding layer 2, an AlGaInAs strained quantum well active layer 3, and an N-type InP cladding layer 4 are successively grown in crystal form on a P-type InP substrate 1 by MOCVD (metal organic chemical vapor deposition).

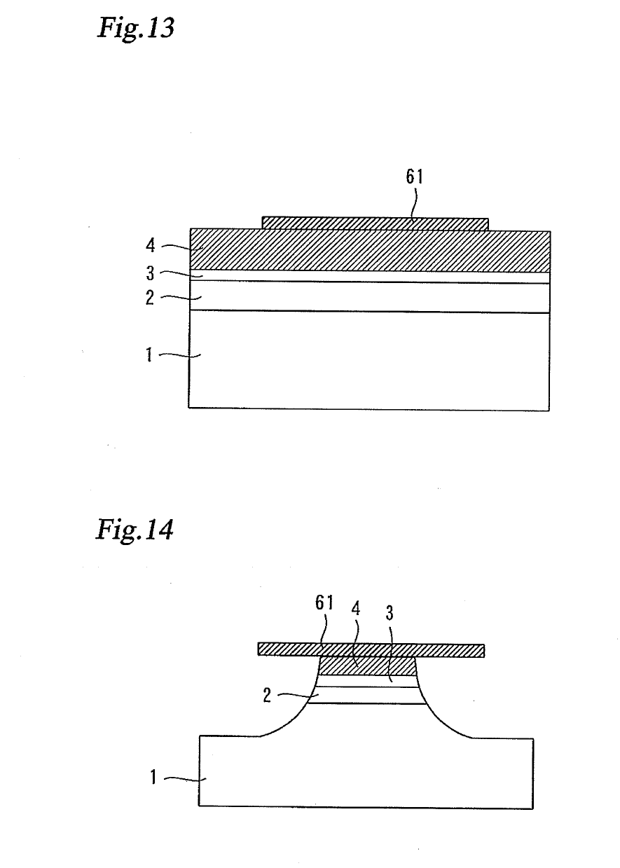

Next, an SiO₂ insulating film 61 is formed on the resulting structure and patterned, as shown in FIG. 13.

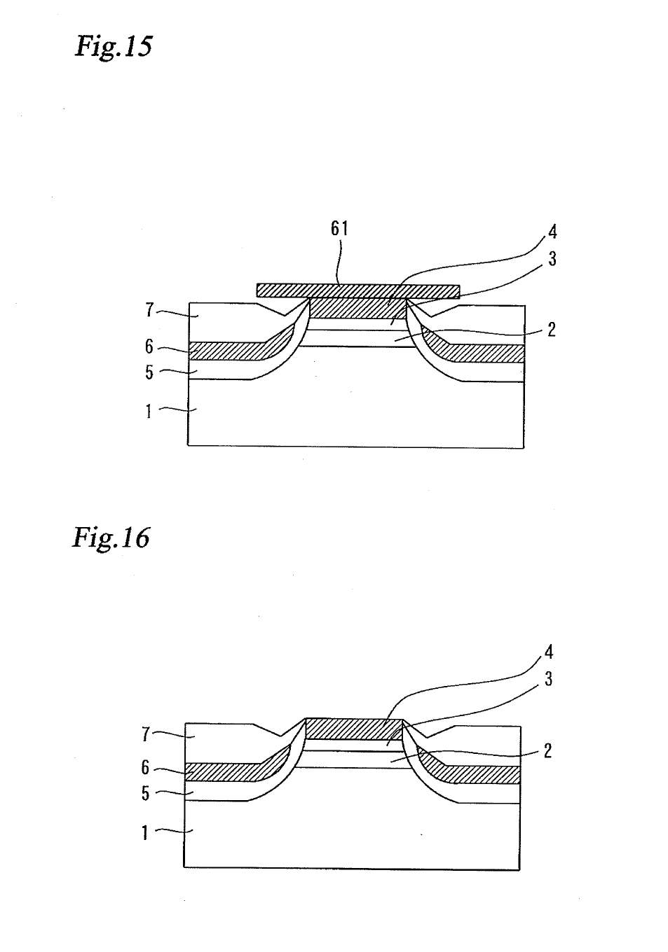

Then, as shown in FIG. 14, a ridge structure is formed by wet etching, etc. A P-type InP buried layer 5, an N-type InP buried layer 6, and a P-type buried layer 7 are then grown by MOCVD, as shown in FIG. 15.

The SiO₂ insulating film 61 is then removed by etching, as shown in FIG. 16.

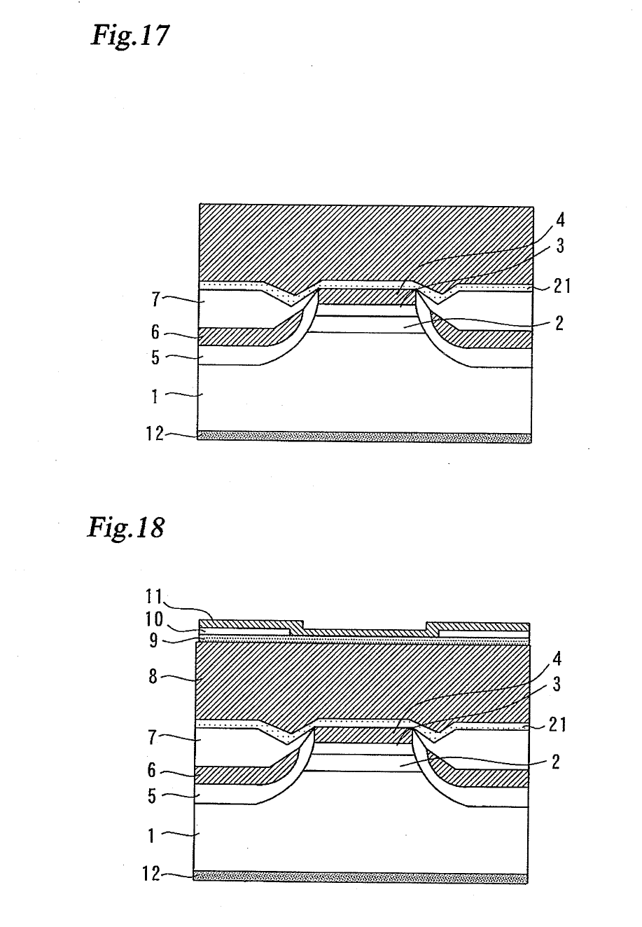

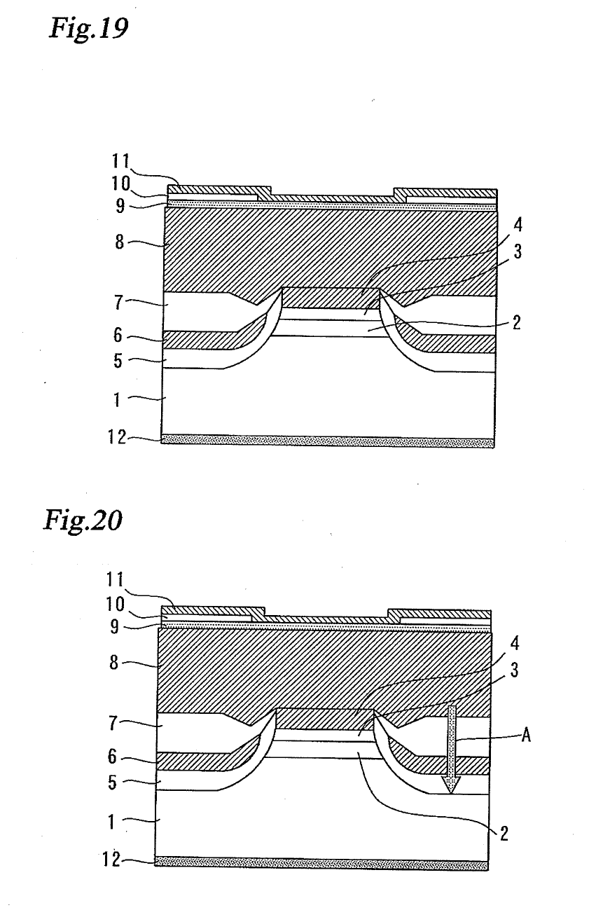

Next, an N-type InGaAsP layer 21, an N-type InP layer 8, and an N-type InP contact layer 9 are grown by MOCVD, as shown in FIG. 17.

An SiO₂ insulating film 10, an N-type electrode 11 of Ti/Pt/Au, and a P-type electrode 12 of AuZn/Pt/Au are then formed, as shown in FIG. 18.

This step completes the manufacture of the semiconductor laser of the first embodiment.

It should be noted that Japanese Laid-Open Patent Publication No. H06-21566 discloses a semiconductor device including N-type and P-type semiconductor layers arranged in an interleaved fashion and also discloses a semiconductor laser including a current blocking having such a device structure. In this laser structure, a p-InGaAsP layer is provided within a p-InP layer (see FIG. 3 of the publication). That is, the p-InGaAsP layer is sandwiched in the p-InP layer.

In the laser structure of the present embodiment described above, on the other hand, an n-InGaAsP layer is provided between a p-InP layer and an n-InP layer. Thus, the semiconductor laser disclosed in the above Japanese Laid-Open Patent Publication No. H06-21566 differs in basic layer structure from the semiconductor laser of the present embodiment.

Further, Japanese Laid-Open Patent Publication Nos. 2001-111170 and 2009-182352 disclose techniques for providing an InGaAsP layer (recombination layer). It should be noted that the above Patent Publication No. 2001-111170 makes no mention of the conductivity type of the InGaAsP layer. However, the InGaAsP layer must be undoped or P-type in order to cause recombination of the minority carrier electrons.

In the laser structure of the present embodiment, on the other hand, the InGaAsP layer provided between the p-InP layer and the n-InP layer is of N-type, which produces the effect described above. Thus, the structure of the present embodiment differs from and has technical advantages over that disclosed in the above Patent Publication No. 2001-111170.

### Second Embodiment

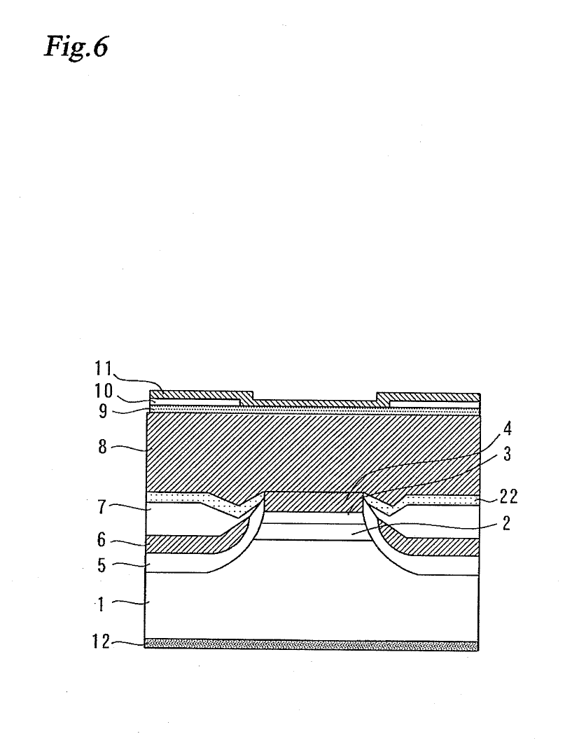

FIG. 6 is a cross-sectional view of a semiconductor laser which is a semiconductor device according to a second embodiment of the present invention. As shown in this figure, the semiconductor laser of the present embodiment includes a P-type InP substrate 1. The semiconductor laser of the present embodiment also includes a P-type InP cladding layer 2 (having a P-type carrier concentration of 1×10¹⁸ cm⁻³), an AlGaInAs strained quantum well active layer 3, and an N-type InP cladding layer 4 (having an N-type carrier concentration of 1×10¹⁸ cm⁻⁸), as seen at the center of the cross-sectional view of FIG. 6.

The semiconductor laser of the present embodiment further includes a P-type InP buried layer 5 (having a P-type carrier concentration of 1×10¹⁸ cm⁻³), an N-type InP buried layer 6 (having an N-type carrier concentration of 1×10¹⁸ cm⁻³), and a P-type InP buried layer 7 (having a P-type carrier concentration of 1×10¹⁸ cm⁻³), as seen at the left and right sides of the cross-sectional view of FIG. 6.

As shown, the semiconductor laser of the present embodiment further includes an N-type InP layer 8 (having an N-type carrier concentration of 1×10¹⁸ cm⁻³), an N-type InP contact layer 9 (having an N-type carrier concentration of 1×10¹⁹ cm⁻³), an SiO₂ insulating film 10, an N-type electrode 11 of Ti/Pt/Au, and a P-type electrode 12 of Ti/Pt/Au.

The semiconductor laser of the second embodiment further includes an N-type InGaAsP buried layer 22 (having an N-type carrier concentration of 1×10¹⁸ cm⁻³). (This layer is hereinafter also referred to simply as the N-type InGaAsP layer 22.)

Unlike the N-type InGaAsP layer 21 of the first embodiment, the N-type InGaAsP layer 22 does not extend over the top surface of the N-type InP cladding layer 4.

The N-type InGaAsP layer 22 has a higher refractive index than the InP layers. Therefore, if the N-type InGaAsP layer 22 extends over the top surface of the N-type InP cladding layer 4, the resulting light intensity distribution pattern in the semiconductor laser is not symmetrical but is biased toward the upper side of the laser. If this bias is significant, there might be degradation of the current-light output characteristic of the semiconductor laser, such as increased threshold current and decreased efficiency of the laser.

In the present embodiment, on the other hand, the N-type InGaAsP layer 22 does not extend over the top surface of the N-type cladding layer 4, thereby avoiding the situation where the light intensity distribution pattern in the semiconductor laser is asymmetrical and is biased toward the upper side of the laser, which situation might result in degradation of the current-light output characteristic of the laser. This means that the present embodiment ensures improvement of the current-light output characteristics of semiconductor lasers.

### Third Embodiment

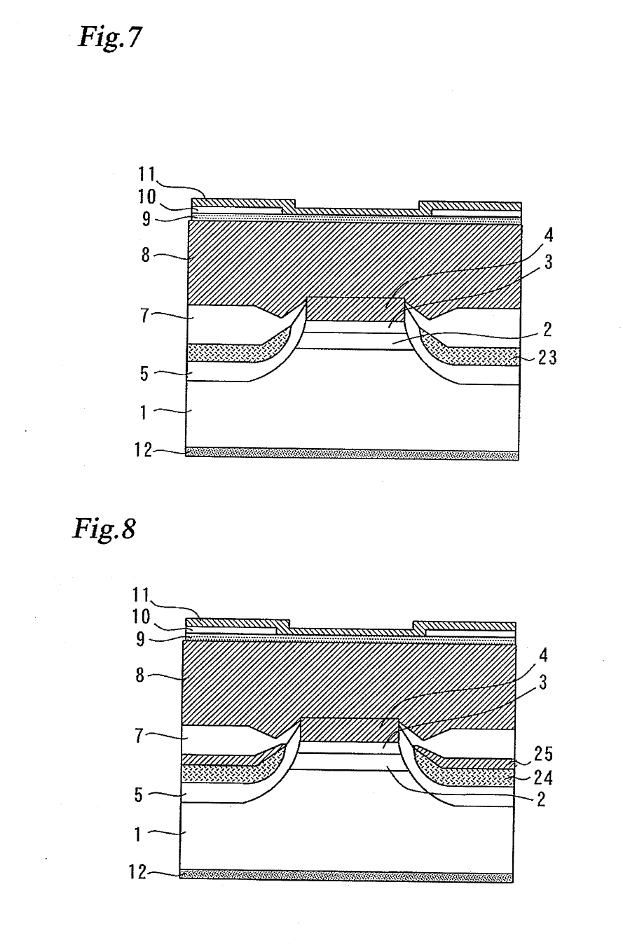

FIG. 7 is across-sectional view of a semiconductor laser which is a semiconductor device according to a third embodiment of the present invention. As shown in this figure, the semiconductor laser of the present embodiment includes a P-type InP substrate 1. The semiconductor laser of the present embodiment also includes a P-type InP cladding layer 2 (having a P-type carrier concentration of 1×10¹⁸ cm⁻³), an AlGaInAs strained quantum well active layer 3, and an N-type InP cladding layer 4 (having an N-type carrier concentration of 1×10¹⁸ cm⁻³), as seen at the center of the cross-sectional view of FIG. 7.

The semiconductor laser of the present embodiment further includes a P-type InP buried layer 5 (having a P-type carrier concentration of 1×10¹⁸ cm⁻³), an N-type InGaAsP buried layer 23 (having an N-type carrier concentration of 1×10¹⁹ cm⁻³), and a P-type InP buried layer 7 (having a P-type carrier concentration of 1×10¹⁸ cm⁻³), as seen at the left and right sides of the cross-sectional view of FIG. 7.

As shown, the semiconductor laser of the present embodiment further includes an N-type InP layer 8 (having an N-type carrier concentration of 1×10¹⁸ cm⁻³), an N-type InP contact layer 9 (having an N-type carrier concentration of 1×10¹⁹ cm⁻³), an SiO₂ insulating film 10, an N-type electrode 11 of Ti/Pt/Au, and a P-type electrode 12 of Ti/Pt/Au.

The laser structure of the present embodiment is characterized by including the N-type InGaAsP buried layer 23, which is substituted for the N-type InP buried layer 6 of the first embodiment. In this structure, the presence of the N-type InGaAsP buried layer 23 serves to increase the potential barrier ΔEc of the P-type InP buried layer 5, thereby reducing the leakage current and improving the current-light output characteristic of the semiconductor laser.

### Fourth Embodiment

FIG. 8 is a cross-sectional view of a semiconductor laser which is a semiconductor device according to a fourth embodiment of the present invention. As shown in this figure, the semiconductor laser of the present embodiment includes a P-type InP substrate 1. The semiconductor laser of the present embodiment also includes a P-type InP cladding layer 2 (having a P-type carrier concentration of 1×10¹⁸ cm⁻³), an AlGaInAs strained quantum well active layer 3, and an N-type InP cladding layer 4 (having an N-type carrier concentration of 1×10¹⁸ cm⁻³), as seen at the center of the cross-sectional view of FIG. 8.

The semiconductor laser of the present embodiment further includes a P-type InP buried layer 5 (having a P-type carrier concentration of 1×10¹⁸ cm⁻³), an N-type InGaAsP buried layer 24 (having an N-type carrier concentration of 1×10¹⁹ cm⁻³), an N-type InP buried layer 25 (having an N-type carrier concentration of 1×10¹⁹ cm⁻³), and a P-type InP buried layer 7 (having a P-type carrier concentration of 1×10¹⁸ cm⁻³), as seen at the left and right sides of the cross-sectional view of FIG. 8.

As shown, the semiconductor laser of the present embodiment further includes an N-type InP layer 8 (having an N-type carrier concentration of 1×10¹⁸ cm⁻³), an N-type InP contact layer 9 (having an N-type carrier concentration of 1×10¹⁹ cm⁻³), an SiO₂ insulating film 10, an N-type electrode 11 of Ti/Pt/Au, and a P-type electrode 12 of Ti/Pt/Au.

Thus, the laser structure of the present embodiment includes the N-type InGaAsP buried layer 24 and the N-type InP buried layer 25, which together serve in place of the N-type InGaAsP buried layer 23 of the third embodiment.

The laser structure of the present embodiment still has a leakage current reducing effect similar to that of the laser structure of the third embodiment. It will be noted that in order to achieve this leakage current reducing effect, the structure of the present embodiment includes the N-type InGaAsP buried layer 24, which is relatively thin, and the N-type InP buried layer 25. The reason for this is because if these layers 24 and 25 are replaced by a single thick InGaAsP layer (e.g., the InGaAsP buried layer 23 of the third embodiment), the resulting light intensity distribution pattern in the semiconductor laser is biased toward that thick InGaAsP layer located away from the active layer 3 since, in general, InGaAsP layers inherently have higher refractive indices than InP layers, so that the current-light output characteristic of the semiconductor laser may be degraded. Thus the laser structure of the fourth embodiment, which is characterized by including the thin N-type InGaAsP buried layer 24 and the N-type InP buried layer 25, avoids the situation where the light intensity distribution pattern in the semiconductor laser is biased in an undesirable manner (which situation may result in degradation of the current-light output characteristic of the laser), and ensures an improved current-light output characteristic of the laser.

### Fifth Embodiment

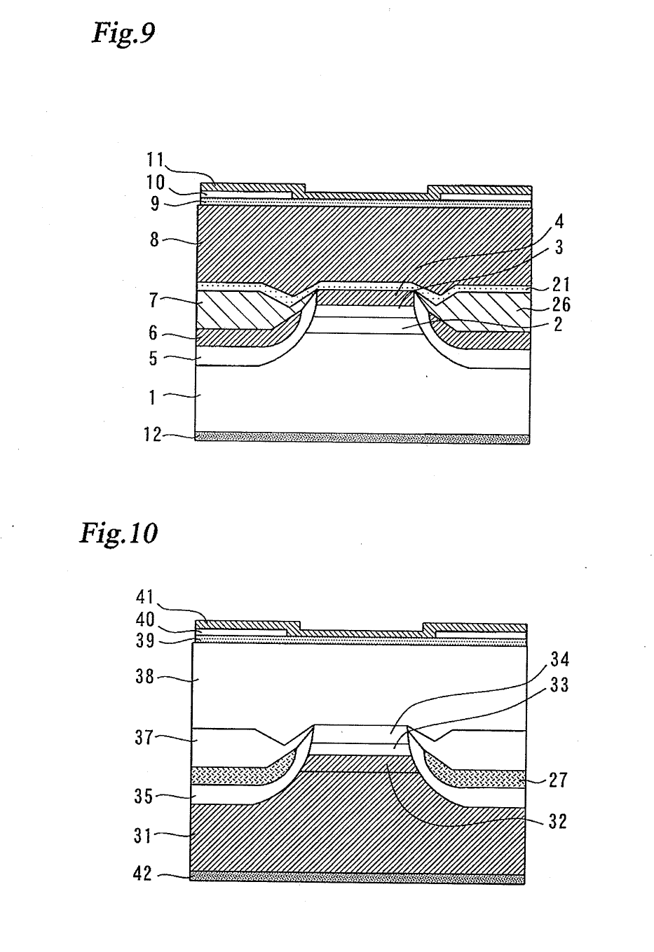

FIG. 9 is a cross-sectional view of a semiconductor laser which is a semiconductor device according to a fifth embodiment of the present invention. As shown in this figure, the semiconductor laser of the present embodiment includes a P-type InP substrate 1. The semiconductor laser of the present embodiment also includes a P-type InP cladding layer 2 (having a P-type carrier concentration of 1×10¹⁸ cm⁻³), an AlGaInAs strained quantum well active layer 3, and an N-type InP cladding layer 4 (having an N-type carrier concentration of 1×10¹⁸ cm⁻³), as seen at the center of the cross-sectional view of FIG. 9.

The semiconductor laser of the present embodiment further includes a P-type InP buried layer 5 (having a P-type carrier concentration of 1×10¹⁸ cm⁻³), an N-type InP buried layer 6 (having an N-type carrier concentration of 1×10¹⁹ cm⁻³), and a semi-insulating InP buried layer 26 (having an Fe concentration of 4×10¹⁶ cm⁻³), as seen at the left and right sides of the cross-sectional view of FIG. 9.

As shown, the semiconductor laser of the present embodiment further includes an N-type InGaAsP layer 21 (having an N-type carrier concentration of 1×10¹⁸ cm⁻³), an N-type InP layer 8 (having an N-type carrier concentration of 1×10¹⁸ cm⁻³), an N-type InP contact layer 9 (having an N-type carrier concentration of 1×10¹⁹ cm⁻³), an SiO₂ insulating film 10, an N-type electrode 11 of Ti/Pt/Au, and a P-type electrode 12 of Ti/Pt/Au.

Thus the laser structure of the present embodiment includes the semi-insulating InP buried layer 26, which is substituted for the P-type InP buried layer 7 of the first embodiment. It should be noted that high speed semiconductor lasers often include a semi-insulating InP buried layer serving to reduce capacitance in the lasers.

The semi-insulating InP buried layer 26 also has the effect of blocking the leakage current. However, this effect is reduced by the diffusion of Zn dopant from the P-type InP buried layer 5 into those portions of the semi-insulating InP buried layer 26 extending along opposite sides of the ridge, resulting in a leakage current flowing by the opposite sides of the ridge.

In the laser structure of the present embodiment, however, the presence of the N-type InGaAsP layer 21 has a leakage current reducing effect similar to that described in connection with the first embodiment. That is, the N-type InGaAsP layer 21 of the present embodiment especially serves to reduce the leakage current flowing by the opposite sides of the ridge, resulting in an improved current-light output characteristic of the laser.

### Sixth Embodiment

FIG. 10 is a cross-sectional view of a semiconductor laser which is a semiconductor device according to a sixth embodiment of the present invention. As shown in this figure, the semiconductor laser of the present embodiment includes an N-type InP substrate 31. The semiconductor laser of the present embodiment also includes an N-type InP layer 32 (having an N-type carrier concentration of 1×10¹⁸ cm⁻³), an AlGaInAs strained quantum well active layer 33, and a P-type InP layer 34 (having a P-type carrier concentration of 1×10¹⁸ cm⁻³), as seen at the center of the cross-sectional view of FIG. 10.

The semiconductor laser of the present embodiment further includes a P-type InP buried layer 35 (having a P-type carrier concentration of 1×10¹⁸ cm⁻³), an N-type InGaAsP buried layer 27 (having an N-type carrier concentration of 1×10¹⁹ cm⁻³), and a P-type InP buried layer 37 (having a P-type carrier concentration of 1×10¹⁸ cm⁻³), as seen at the left and right sides of the cross-sectional view of FIG. 10.

As shown, the semiconductor laser of the present embodiment further includes a P-type InP layer 38 (having a P-type carrier concentration of 1×10¹⁸ cm⁻³), a P-type InGaAs contact layer 39 (having a P-type carrier concentration of 1×10¹⁹ cm⁻³), an SiO₂ insulating film 40, a P-type electrode 41 of Ti/Pt/Au, and an N-type electrode 42 of Ti/Pt/Au.

Whereas the semiconductor laser of the third embodiment includes a P-type InP substrate, the semiconductor laser of the present embodiment includes an N-type InP substrate. However, the laser structure of the present embodiment still has a leakage current reducing effect similar to that of the laser structure of the third embodiment.

### Seventh Embodiment

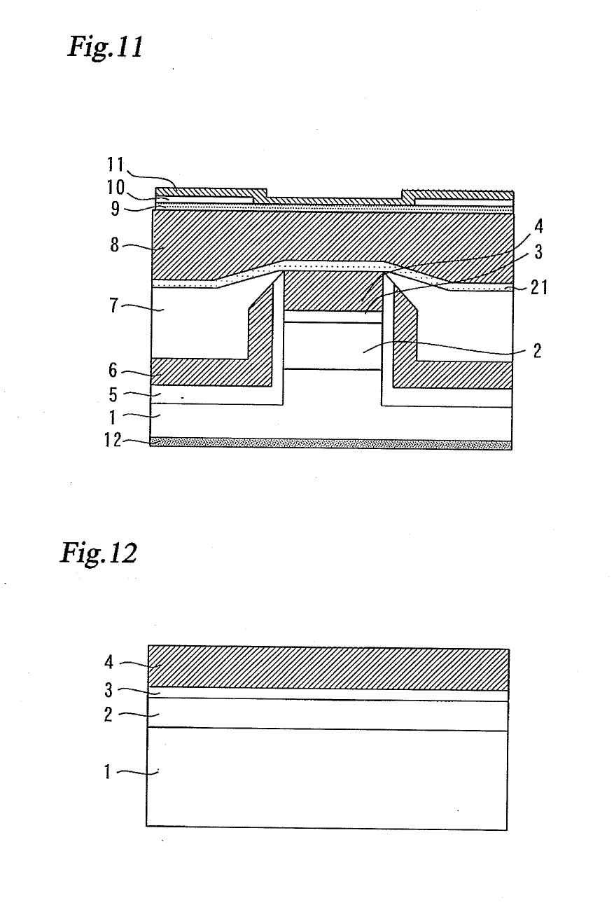

FIG. 11 is a cross-sectional view of a semiconductor laser which is a semiconductor device according to a seventh embodiment of the present invention. As shown in this figure, the semiconductor laser of the present embodiment includes a P-type InP substrate 1. The semiconductor laser of the present embodiment also includes a P-type InP cladding layer 2 (having a P-type carrier concentration of 1×10¹⁸ cm⁻³), an AlGaInAs strained quantum well active layer 3, and an N-type InP cladding layer 4 (having an N-type carrier concentration of 1×10¹⁸ cm⁻³), as seen at the center of the cross-sectional view of FIG. 11.

The semiconductor laser of the present embodiment further includes a P-type InP buried layer 5 (having a P-type carrier concentration of 1×10¹⁸ cm⁻³), an N-type InP buried layer 6 (having an N-type carrier concentration of 1×10¹⁹ cm⁻³), and a P-type InP buried layer 7 (having a P-type carrier concentration of 1×10¹⁸ cm⁻³), as seen at the left and right sides of the cross-sectional view of FIG. 11.

As shown, the semiconductor laser of the present embodiment further includes an N-type InGaAsP layer 21 (having an N-type carrier concentration of 1×10¹⁸ cm⁻³), an N-type InP layer 8 (having an N-type carrier concentration of 1×10¹⁸ cm⁻³), an N-type InP contact layer 9 (having an N-type carrier concentration of 1×10¹⁹ cm⁻³), an SiO₂ insulating film 10, an N-type electrode 11 of Ti/Pt/Au, and a P-type electrode 12 of Ti/Pt/Au.

In the third embodiment, the ridge of the semiconductor laser is formed by wet etching. Therefore, the opposite sides of the ridge are gradually sloped. In the present embodiment, on the other hand, the ridge of the semiconductor laser is formed by dry etching. Therefore, the opposite sides of the ridge of the present embodiment are perpendicular to the substrate surface, so that the buried layers have configurations as shown in FIG. 11. The laser structure of the present embodiment also has a leakage current reducing effect similar to that of the laser structure of the third embodiment.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2010-145076, filed on Jun. 25, 2010 including specification, claims, drawings and summary, on which the Convention priority of the present application is based, are incorporated herein by reference in its entirety.

1. A semiconductor device comprising:
a current blocking layer structure including a first P-type semiconductor layer, a first N-type semiconductor layer, and a second P-type semiconductor layer, stacked on one another, in that order;
a second N-type semiconductor layer covering said current blocking layer structure; and
a third N-type semiconductor layer located between said second N-type semiconductor layer and said second P-type semiconductor layer of said current blocking layer structure and in contact with said second P-type semiconductor layer, said third N-type semiconductor layer having a smaller bandgap energy than said second N-type semiconductor layer so that said second P-type semiconductor layer has a higher potential barrier than when said third N-type semiconductor layer is absent.

2. The semiconductor device according to claim 1, further comprising a ridge, wherein said second N-type semiconductor layer is in contact with said current blocking layer and said ridge.

3. The semiconductor device according to claim 2, wherein:
said ridge includes an active layer for receiving a current and emitting laser light and further includes cladding layers sandwiching said active layer;
said current blocking layer structure is disposed on opposite sides of and sandwiches said ridge; and
said third N-type semiconductor layer covers said ridge and said current blocking layer structure.

4. The semiconductor device according to claim 1, wherein said third N-type semiconductor layer is InGaAsP.

5. The semiconductor device according to claim 1, wherein said third N-type semiconductor layer is AlGaInAs.

6. The semiconductor device according to claim 1, wherein said third N-type semiconductor layer has a bandgap wavelength in a range from 1.05 μm to 1.2 μm.

7. A semiconductor device comprising a current blocking layer structure including a P-type semiconductor layer, an N-type semiconductor layer, and a second P-type semiconductor layer, stacked on one another, in that order, wherein said N-type semiconductor layer is one of InGaAsP and AlGaInAs.

8. A semiconductor device comprising a current blocking layer structure including a P-type semiconductor layer, an N-type semiconductor layer, and a semi-insulating semiconductor layer, stacked on one another, in that order, wherein said N-type semiconductor layer is one of InGaAsP and AlGaInAs.
